(19) United States
(12) Patent Application Publication
(10) Pub. No.: US 2025/0285919 A1
(43) Pub. Date: Sep. 11, 2025

(54) Aluminum Oxide Isolation for Hybrid Bonding

(71) Applicant: Applied Materials, Inc., Santa Clara, CA (US)

(72) Inventors: William Oghandi CHARLES, Winchester, MA (US); Amit PRAKASH, Santa Clara, CA (US); Shubhendra Kumar JAIN, Belmont, MA (US); Mariia GORCHICHKO, San Jose, CA (US); Joshua Stuart HOLT, Sunnyvale, CA (US); Archana KUMAR, Mountain View, CA (US); Roger Allan QUON, Rhinebeck, NY (US); Benjamin D. BRIGGS, Merrimack, NH (US); Stephen WEEKS, Morrisville, VT (US); Yoocharn JEON, Palo Alto, CA (US); Ryan Thomas LEY, Mountain View, CA (US)

(21) Appl. No.: 18/599,846

(22) Filed: Mar. 8, 2024

(51) Int. Cl. H01L 21/768; H01L 21/02; H01L 21/321

(52) U.S. Cl. CPC H01L 21/7685; H01L 21/02178; H01L 21/3212; H01L 21/76877; H01L 21/76898

(57) ABSTRACT

A method for preparing a substrate for hybrid bonding by forming an isolation barrier around metal contacts on the substrate to separate the metal contacts from an aluminum oxide (Al₂O₃) bonding layer prior to performing the hybrid bonding process. A method may include forming an aluminum oxide layer on the substrate as a bonding layer for a hybrid bonding process where the aluminum oxide layer is formed on a dielectric material on the substrate that is different from a material of the aluminum oxide layer, forming a metal contact on the substrate that penetrates through the aluminum oxide layer, and forming an isolation barrier around the metal contact where the isolation barrier prevents adjacent portions of the aluminum oxide layer next to the metal contact from completely covering an uppermost bonding surface of the metal contact during an annealing process of the hybrid bonding process.

### FIELD

Embodiments of the present principles generally relate to semiconductor processing of semiconductor substrates.

### BACKGROUND

Hybrid bonding is the joining or bonding of more than one type of material. In semiconductor manufacturing, hybrid bonding is used to package devices by bonding one substrate or die to another substrate or die to join not only dielectric surfaces but to also join metal interconnects or contacts together. Traditionally, dielectrics, such as silicon dioxide, provide most of the bonding strength in a hybrid bond. As the density of the interconnects and contacts increases, the dielectric material bonding area decreases. To help ensure a successful bond with a die or substrate with a high density of contacts, dielectric materials with higher bonding strengths, such as aluminum oxide, may be introduced into the manufacturing processes. However, the inventors have observed that during hybrid bonding processes that use aluminum oxide, poor bonding occurs between the metal interconnects and contacts, leading to low yields.

Accordingly, the inventors have provided methods for improving hybrid bonding performance of substrates with aluminum oxide bonding layers.

### SUMMARY

Methods for improving hybrid bonding performance by providing an aluminum oxide crystalline growth barrier are provided herein.

In some embodiments, a method for processing a substrate may comprise providing a first substrate for a hybrid bonding process and forming, on the first substrate, a hybrid bonding layer that comprises a dielectric layer, a metal contact, and an isolation barrier surrounding the metal contact that is between the metal contact and at least a portion of the dielectric layer.

In some embodiments, the method may further include hybrid bonding the first substrate to a second substrate via the hybrid bonding layer, an isolation barrier that is formed of metal or dielectric material, a metal contact is formed of copper, an isolation barrier that is formed of silicon dioxide material, a dielectric layer that is an aluminum oxide (Al₂O₃) layer, an aluminum oxide layer that is formed on a dielectric material on the first substrate that is different from a material of the aluminum oxide layer, an isolation barrier that extends from an uppermost surface of the dielectric material to at least an uppermost surface of the aluminum oxide layer, a metal contact that is first formed in the dielectric material, a recess that is formed a distance from the metal contact in the dielectric material for acceptance of aluminum oxide material, an aluminum oxide that is deposited globally on the substrate, and a substrate that undergoes a chemical mechanical planarization (CMP) process to form the isolation barrier around the metal contact with a width equal to the distance from the metal contact, a distance that is greater than a maximum misalignment tolerance value of the hybrid bonding process such that aluminum oxide migration over the metal contact is circumvented during a subsequent annealing process of the hybrid bonding process up to the maximum misalignment tolerance value, an aluminum oxide layer that is deposited first on the dielectric material, a metal contact that is formed through the aluminum oxide layer, a selective etch process that is used to create a gap surrounding the metal contact, an isolation material that is globally deposited to gapfill the gap surrounding the metal contact, and a chemical mechanical planarization (CMP) process that is used to form the isolation barrier around the metal contact with a width equal to the gap surrounding the metal contact, a width that is greater than a maximum misalignment tolerance value of the hybrid bonding process such that aluminum oxide migration over the metal contact is circumvented during a subsequent annealing process of the hybrid bonding process up to the maximum misalignment tolerance value, a maximum width of the isolation barrier that is determined based on a maximum acceptable leakage current through the dielectric layer between adjacent metal contacts, and/or an isolation barrier that is a distance from the metal contact and where the distance between the isolation barrier and the metal contact includes a portion of the dielectric layer with insufficient volume to completely cover the metal contact during a subsequent annealing process of the hybrid bonding process.

In some embodiments, a substrate prepared for hybrid bonding may comprise a dielectric material, a dielectric bonding layer formed on the dielectric material, at least one metal contact, wherein an uppermost surface of the at least one metal contact is exposed through the dielectric bonding layer, and at least one isolation barrier formed around the at least one metal contact that surrounds the at least one metal contact.

In some embodiments, the substrate may further include a dielectric bonding layer that is an aluminum oxide (Al₂O₃) layer where at least one of the at least one metal contact is copper, and where the isolation barrier is formed of metal or dielectric material, an isolation barrier that extends from an uppermost surface of the dielectric material to at least an uppermost surface of the dielectric bonding layer, and/or a device that comprises the substrate and another substrate that is hybrid bonded to the substrate via the dielectric bonding layer and the at least one metal contact.

In some embodiments, a non-transitory, computer readable medium having instructions stored thereon that, when executed, cause a method for processing a substrate, the method may comprise providing a substrate for a hybrid bonding process and forming, on the substrate, a hybrid bonding layer that comprises a dielectric layer, a metal contact, and an isolation barrier surrounding the metal contact between the metal contact and at least a portion of the dielectric layer, and/or a dielectric layer that is an aluminum oxide (Al₃O₂) layer formed on a dielectric material on the substrate and a metal contact that is first formed in the dielectric material, a recess that is formed a distance from the metal contact in the dielectric material for acceptance of aluminum oxide material, an aluminum oxide that is deposited globally on the substrate, and a substrate that undergoes a chemical mechanical planarization (CMP) process to form the isolation barrier around the metal contact with a width equal to the distance from the metal contact or an aluminum oxide layer that is deposited first on the dielectric material, a metal contact that is formed through the aluminum oxide layer, a selective etch process that is used to create a gap surrounding the metal contact, an isolation material that is globally deposited to gapfill the gap surrounding the metal contact, and a chemical mechanical planarization (CMP) process that is used to form the isolation barrier around the metal contact with a width equal to the gap surrounding the metal contact.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method for preparing a substrate for hybrid bonding with aluminum oxide isolation barriers formed of substrate material in accordance with some embodiments of the present principles.

FIG. 2 is a method for preparing a substrate for hybrid bonding where aluminum oxide isolation barriers are formed around metal contacts in accordance with some embodiments of the present principles.

FIG. 3 depicts a cross-sectional view of an aluminum oxide isolation barrier formed from substrate material in preparation for a hybrid bonding process in accordance with some embodiments of the present principles.

FIG. 4 depicts a cross-sectional view of an aluminum oxide isolation barrier formed on a substrate in preparation for a hybrid bonding process in accordance with some embodiments of the present principles.

FIG. 5 depicts a cross-sectional view of an aluminum oxide isolation barrier impacts on leakage currents in accordance with some embodiments of the present principles.

FIG. 6 depicts a top-down view of an aluminum oxide isolation barrier formed a distance away from a metal contact in accordance with some embodiments of the present principles.

FIG. 7 depicts a cross-sectional view of an aluminum oxide isolation barrier formed a distance away from a metal contact in accordance with some embodiments of the present principles.

FIG. 8 depicts a cross-sectional view of substrates with a bonding misalignment in accordance with some embodiments of the present principles.

FIG. 9 depicts cross-sectional views of a hybrid bonding process without an aluminum oxide isolation barrier of the present principles.

FIG. 10 depicts cross-sectional views of a hybrid bonding process using an aluminum oxide isolation barrier in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide improved hybrid bonding performance by incorporating an aluminum oxide crystalline growth barrier. The aluminum oxide isolation barrier surrounds the metal contacts on a substrate that uses an aluminum oxide bonding layer for a hybrid bonding process. The isolation barrier prevents migration of aluminum oxide over copper contacts during annealing of the bonded substrates, providing both high dielectric and contact bonding strengths. The high bonding strengths provided by the present methods enable increased metal contact densities to be achieved, allowing for scaling of semiconductor devices. The present techniques may be performed prior to a bonding layer deposition on a substrate or after the bonding layer deposition on the substrate, providing processing flexibility and easy integration into existing hybrid bonding preparation processes.

Traditional dielectrics such as silicon dioxide limit the scaling of devices due to the bonding strength of the dielectric material. In order to increase the metal contact densities, the bonding strength of the dielectrics used in hybrid bonding must be increased as the bonding strength of the metal contacts is relatively low compared to the dielectric bonding strength. Aluminum oxide is being considered as a replacement for dielectric bonding material such as silicon dioxide. Aluminum oxide has a 40% to 80% increase in bonding strength compared to that of silicon dioxide. However, the inventors have found that when a substrate with aluminum oxide and metal contacts are bonded together and then annealed, the aluminum oxide migrates over the top surfaces of the metal contacts and prevents the metal contacts from bonding. The inventors believe that the migration of the aluminum oxide is caused by low-temperature crystallization of the aluminum oxide. Typically, aluminum oxide crystallizes at a temperature of approximately 850 degrees Celsius. Hybrid bonding annealing temperatures are generally around 350 degrees Celsius. The inventors believe that the crystals of the metal material (e.g., copper, etc.) of the metal contacts act as a catalyst for the crystallization of the aluminum oxide which lowers the crystallization temperature to at or below the annealing temperature. The crystallized aluminum then migrates/diffuses over the surfaces of the metal contacts due to annealing process performed during substrate/wafer bonding (e.g., the aluminum oxide has a higher diffusion rate than copper at a given temperature causing aluminum oxide to migrate).

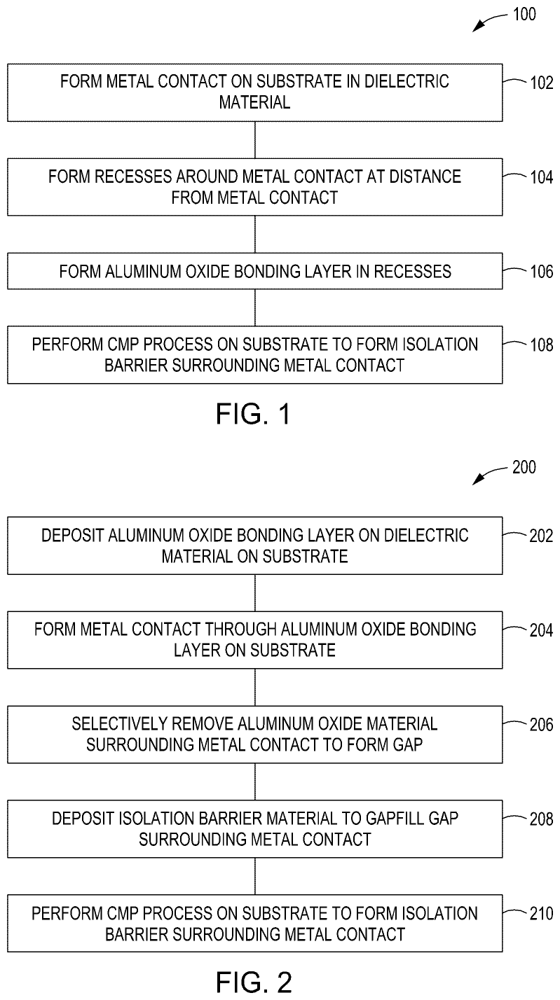

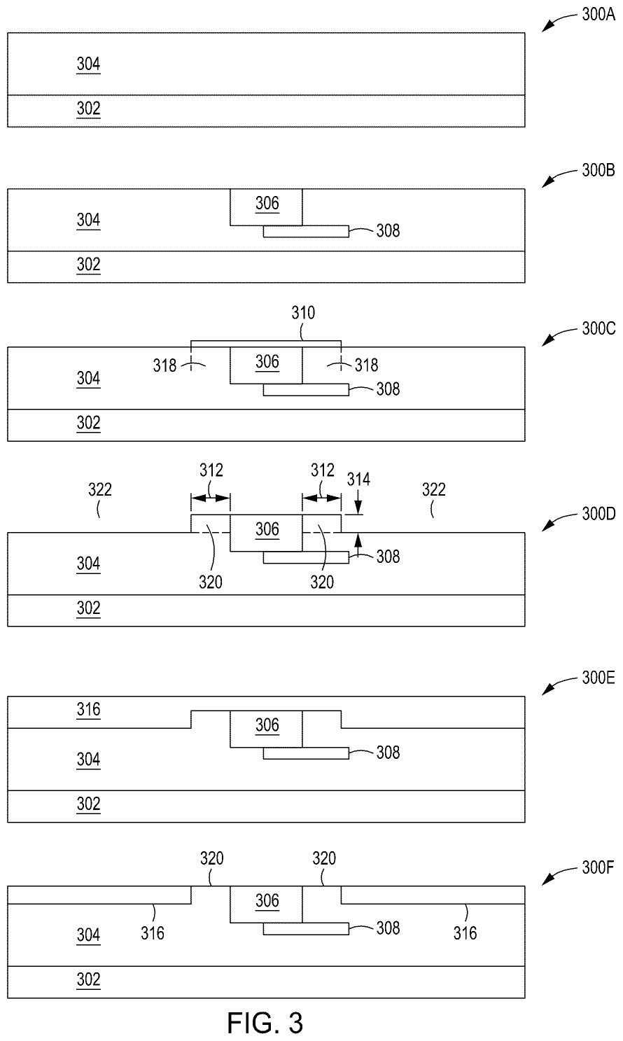

The inventors found that to successfully bond using an aluminum oxide bonding layer, the aluminum oxide crystallization caused by contacting the copper contact and the subsequent migration should be minimized. In the present methods, suppression of the aluminum oxide migration during hybrid bonding may be accomplished by providing an aluminum oxide isolation barrier that surrounds the metal contacts. In some embodiments, as in method 100 of FIG. 1, a substrate 302 may be prepared for a hybrid bonding process by forming an aluminum oxide isolation barrier from a dielectric material 304 (e.g., silicon dioxide, etc.) previously deposited on the substrate 302 as depicted in a view 300A of FIG. 3. The substrate 302 may be formed, at least in part, of silicon dioxide materials. In some embodiments, the substrate 302 may have undergone prior device manufacturing and/or packaging processes to prepare the substrate 302 for bonding to another substrate and/or die. In block 102 of the method 100 in FIG. 1, a metal contact 306 is formed in the dielectric material 304 on the substrate 302 as depicted in a view 300B of FIG. 3. In some instances, the metal contact 306 may be formed to connect other interconnects 308 and the like embedded in the substrate 302. The metal contact 306 allows for connections to be formed with other substrates bonded to the substrate 302.

In block 104, recesses 322 are formed around the metal contact 306 at a distance form the metal contact 306. In some embodiments, a photo resist pattern 310 may be used to protect areas of the substrate 302 from an etching process that forms the recesses. The photo resist pattern 310 may cover the whole of the metal contact and a portion 318 of the dielectric material 304 that surrounds the metal contact 306 as depicted in a view 300C of FIG. 3. In some embodiments, the photo resist pattern 310 may cover only a portion of the metal contact 306 or none of the metal contact 306 and the portion 318 of the dielectric material 304 that surrounds the metal contact 306. As the etching process used to etch the dielectric material 304 can be selective of dielectric material over metal material, protection of the metal contact 306 by covering the metal contact 306 with photo resist is optional. The etching process removes some of the dielectric material 304 to a depth 314 that determines a thickness of a subsequently deposited aluminum oxide bonding layer as depicted in a view 300D of FIG. 3. In some embodiments, the thickness of the aluminum oxide bonding layer may be from approximately 30 nm to approximately 50 nm.

A width 312 of the dielectric material 304 surrounding the metal contact 306 is the distance or width of the aluminum oxide isolation barrier 320 that surrounds the metal contact 306. The lower limit of the width 312 is the minimum separation of the metal contact 306 and the aluminum oxide bonding layer 316 to prevent crystallization and subsequent migration of the aluminum oxide over the surface of the metal contact 306. The lower limit may also be based on an acceptable misalignment tolerance value. The width 312 would be greater than the acceptable misalignment tolerance value such that at maximum misalignment, the metal of the metal contact will only come into contact with the aluminum oxide isolation barrier and will not come into contact with the aluminum oxide. The upper limits of the width 312 is the minimum acceptable bonding strength reduction due to the diminished area of the aluminum oxide bonding layer from the incorporation of the aluminum oxide isolation barrier.

In block 106, an aluminum oxide bonding layer 316 is formed on the substrate 302 by depositing aluminum oxide onto the substrate 302. In some embodiments, as depicted in a view 300E of FIG. 3, the aluminum oxide deposition process includes deposition of aluminum oxide on the entire substrate in a global fashion, filling the recesses 322 and covering the metal contact 306. In block 108, a CMP process is then performed to remove excess aluminum oxide from the aluminum oxide bonding layer 316 on the substrate 302, leaving the aluminum oxide isolation barrier 320 in place as depicted in a view 300F of FIG. 3. The aluminum oxide isolation barrier 320 prevents the aluminum oxide bonding layer 316 from touching and subsequently interacting with the metal, such as copper, of the metal contact 306 and lowering the crystallization temperature of the aluminum oxide. The aluminum oxide isolation barrier 320, thus, prevents the migration of the aluminum oxide over the top of the metal contact 306 during subsequent annealing processes associated with the hybrid bonding process. As the aluminum oxide isolation barrier 320 is formed from the dielectric material 304, the aluminum oxide isolation barrier 320 of method 100 does not have leakage current issues. Although aluminum oxide has a 40% to 80% increase in bonding strength over dielectric materials such as silicon dioxide, silicon dioxide and similar materials still provide very good bonding strength. As such, the minimal reduction in aluminum oxide bonding area in the formation of the aluminum oxide isolation barrier out of the dielectric material only slightly impacts the overall hybrid bonding strength of the substrate 302 while preventing crystallization and migration of the aluminum oxide.

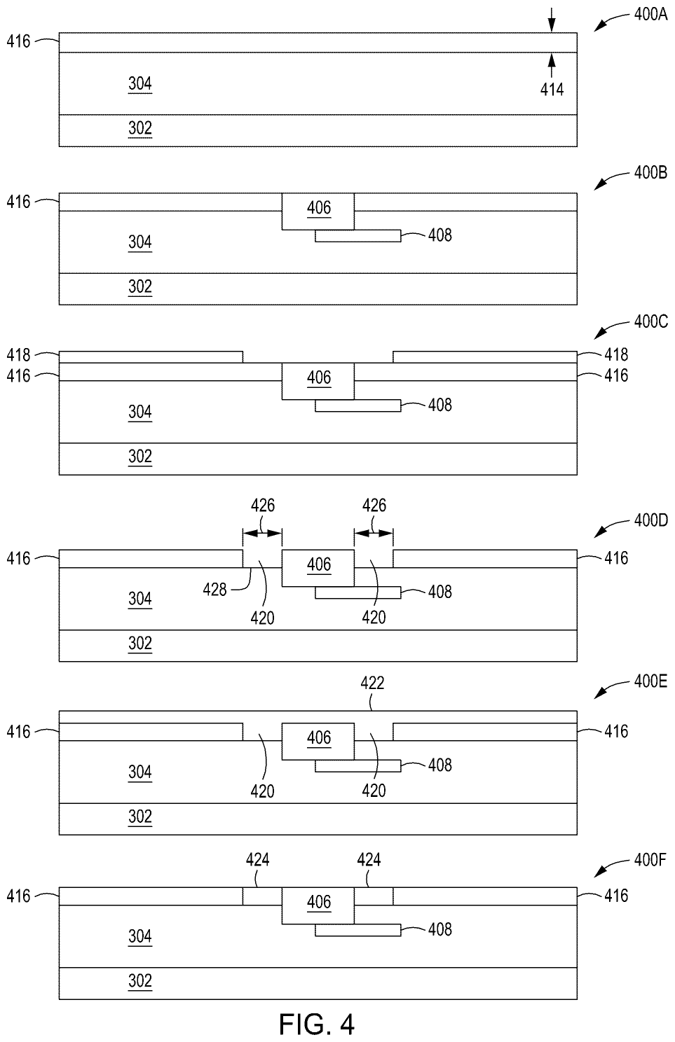

In some embodiments, the aluminum oxide isolation barrier may be formed of a material different from the dielectric material used in the substrate. FIG. 2 is a method 200 that deposits the aluminum oxide isolation barrier onto the substrate. In block 202, an aluminum oxide bonding layer 416 is deposited onto the dielectric material 304 of the substrate 302 as depicted in view 400A of FIG. 4. The aluminum oxide bonding layer 416 may have a thickness 414 of approximately 30 nm to approximately 50 nm. In block 204, the metal contact 406 is formed through the aluminum oxide bonding layer 416 and into the dielectric material 304 as depicted in a view 400B of FIG. 4. In some instances, the metal contact 406 may be formed to connect other interconnects 408 and the like that are embedded in the substrate 302. The metal contact 406 allows for connections within the substrate 302 to be connected to other connections within other substrates bonded to the substrate 302. In block 206, the aluminum oxide material of the aluminum oxide bonding layer 416 surrounding the metal contact 406 is selectively removed. In some embodiments, a photo resist pattern 418 may be used to protect portions of the aluminum oxide bonding layer 416 from a selective etching process (selective of aluminum oxide material over metal material of the metal contact) as depicted in a view 400C of FIG. 4. A portion of the aluminum oxide bonding layer 416 is then removed to expose a surface 428 of the dielectric material 304 underlying the aluminum oxide bonding layer 416 to form a gap 420 around the metal contact 406 as depicted in view 400D of FIG. 4. A width 426 of the gap 420 (or width of the aluminum oxide isolation barrier 424) is the distance at which the aluminum oxide isolation barrier will surround the metal contact 406. In some embodiments, the lower limit of the width 426 will be the necessary width to prevent crystallization and migration of the aluminum oxide during annealing. In some embodiments, the lower limit of the width 426 will be based on the capability of the manufacturing process that is present to gapfill the gap 420 with aluminum oxide isolation barrier material.

In block 208, aluminum oxide isolation barrier material 422 is deposited on the substrate 302 to gapfill the gap 420 surrounding the metal contact 406 as depicted in a view 400E of FIG. 4. In block 210, a CMP process is then performed to remove excess aluminum oxide isolation barrier material 422 on the substrate 302, forming the aluminum oxide isolation barrier 424 in the gap 420 as depicted in a view 400F of FIG. 4. The aluminum oxide isolation barrier 424 prevents the aluminum oxide bonding layer 416 from touching and subsequently interacting with the metal, such as copper, of the metal contact 406 and lowering the crystallization temperature of the aluminum oxide. The aluminum oxide isolation barrier 424 prevents the migration of the aluminum oxide over the top of the metal contact 406 during subsequent annealing processes associated with the hybrid bonding process. As aluminum oxide has a 40% to 80% increase in bonding strength over dielectric materials such as silicon dioxide, the minimal reduction in aluminum oxide bonding area in the formation of the aluminum oxide isolation barrier 424 only slightly impacts the overall hybrid bonding strength of the substrate 302 while preventing crystallization and migration of the aluminum oxide. In some embodiments, the aluminum oxide isolation barrier 424 is formed from depositing a dielectric material and does not have leakage current issues.

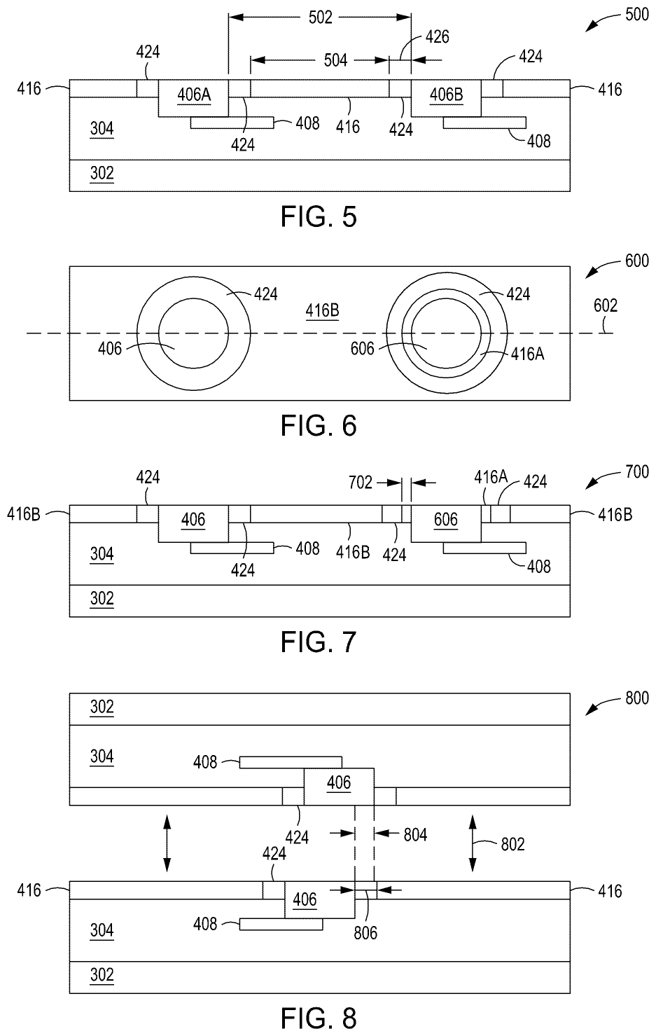

In some embodiments, the aluminum oxide isolation barrier 424 may be formed of materials with some level of increased conductivity (e.g., tantalum nitride and the like) compared to the underlying dielectric material such as dielectric material 304. In effect, the aluminum oxide isolation barrier 424 will reduce the original insulative distance 502 between metal contacts on the substrate 302 to a reduced insulative distance 504 as depicted in a view 500 of FIG. 5. In the example of FIG. 5, the original insulative distance 502 has been reduced by 2X (two times) the width 426 of the aluminum oxide isolation barrier 424 to yield the reduced insulative distance 504. Care must be taken in selection of the width 426 of the aluminum oxide isolation barrier 424 to ensure that the width 426 is sufficient to mitigate crystallization and subsequent migration of the aluminum oxide over the metal contacts 406A, 406B. The selection of the width 426 must also ensure that the width 426 produces a leakage current less than a leakage current requirement for a particular application (e.g., high density contacts, low density contacts, high leakage current tolerances, low leakage current tolerances, etc.). Metal materials, such as cobalt and the like, can be used as aluminum oxide isolation barrier materials but with a significant impact on leakage current values and most likely only in low density applications and similar. In some embodiments, the allowable leakage current is less than approximately 2× (two times) that of aluminum oxide or silicon dioxide while still suppressing the crystallization of the aluminum oxide. In some embodiments, the allowable leakage current may be approximately 100 nA/cm² or less.

The inventors have also discovered that total elimination of the aluminum oxide crystallization and migration is not necessary for successful hybrid bonding. In some embodiments, the aluminum oxide isolation barrier 424 can be used to limit the migration of the aluminum oxide to prevent total coverage of an upper surface of the metal contact 606 as depicted in a view 600 of FIG. 6. The aluminum oxide isolation barrier 424 has been formed surrounding the metal contact 606 but not directly adjacent to the metal contact 606. In some embodiments, the aluminum oxide isolation barrier 424 surrounds the metal contact and divides the aluminum oxide bonding layer 416 into a first portion 416A of the aluminum oxide bonding layer 416 and a second portion 416B of the aluminum oxide bonding layer 416. A cross-sectional view 700 of the cutline 602 is depicted in FIG. 7. The aluminum oxide isolation barrier 424 of the metal contact 606 has been formed a distance 702 from the metal contact 606. The volume of aluminum oxide of the first portion 416A of the aluminum oxide bonding layer 416 remaining between the metal contact 606 and the aluminum oxide isolation barrier 424 should be less than that required to crystallize and migrate completely over a top surface of the metal contact 606. The inventors found that contact bonding can still occur despite partial crystallization and migration of the aluminum oxide on the bonding surface of the metal contact 606. The significance of the discovery is that high tolerance formation of the aluminum oxide isolation barrier 424 around the metal contact 606 is not necessary for interconnect hybrid bonding, allowing for some error and/or defects and the like without significantly impacting bonding yield. In some embodiments, the volume of the first portion 416A of the aluminum oxide bonding layer 416 is zero, as the aluminum oxide isolation barrier 424 is formed directly adjacent to the metal contact 406.

The present methods may also be used to account for bonding misalignment causing aluminum oxide migration during hybrid bonding processes as depicted in a view 800 of FIG. 8. In general, production tolerances for alignment will allow for a slight misalignment while still yielding high interconnect bonding success. In traditional processes that account for misalignment, the concern is that the material of a contact, such as copper, will, if misaligned, migrate into the dielectric of the substrate to which the contact is being bonded. However, the inventors have found that misalignment of the bonded surfaces which use aluminum oxide as a bonding layer will cause the aluminum oxide to crystallize and migrate over the top surfaces of the metal contacts, leading to contact bonding failures during bonding. FIG. 8 depicts a misalignment tolerance value 804 between two substrates being bonded together with both substrates using an aluminum oxide bonding layer 416. As the substrates are brought together 802, the metal of the metal contact 406 will come into contact with the surface of the substrate other than the surface of the metal contacts. If the surface of the substrate contains aluminum oxide, the aluminum oxide will crystallize and migrate between the contact bonding surfaces and prevent the contacts from bonding. By ensuring that the aluminum oxide isolation barrier 424 has a width 806 that is greater than a misalignment tolerance value 804, even when the substrates are misaligned, the metal contact surfaces will not come into contact with aluminum oxide and no aluminum oxide crystallization and migration will occur.

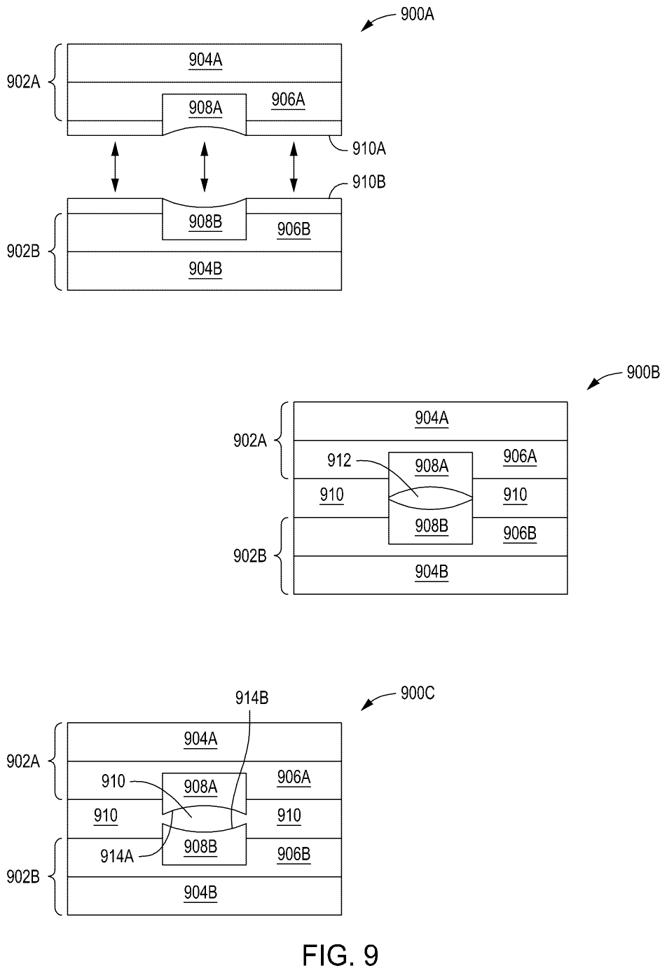

The above methods can be used to enhance the bonding strength and yield of hybrid bonding processes. For example, as depicted in a view 900A of FIG. 9, the substrates 902A, 902B may be bonded together. The substrates 902A, 902B have silicon layers 904A, 904B, silicon dioxide layers 906A, 906B, and metal contacts 908A, 908B. The bonding layers are aluminum oxide layers 910A, 910B. As depicted in a view 900B of FIG. 9, when the substrates 902A, 902B with aluminum oxide layers 910A, 910B are brought into contact with each other (bonded), the aluminum oxide layers 910A, 910B form a single aluminum oxide bonded layer 910. The metal contacts 908A, 908B have not yet bonded together, and a gap 912 exists between the metal contacts 908A, 908B due to the recesses formed on each metal contact during CMP processing. In order to close the gap 912 and form a continuous contact, the substrates 902A, 902B undergo an annealing process at temperatures up to 400 degrees Celsius. The inventors have found that during the annealing process, the aluminum oxide material of the aluminum oxide layers crystallize at a dramatically lower temperature (at 400 degrees Celsius or less compared to a normal crystallization temperature of 850 degrees Celsius) due to the material (e.g., copper, etc.) of the metal contacts acting as a crystallization catalyst. As depicted in a view 900C of FIG. 9, the substantially lowered crystallization temperature allows the single aluminum oxide bonded layer 910 to crystallize and migrate over the surfaces 914A, 914B of the metal contacts 908A, 908B during the annealing process, preventing the metal contacts 908A, 908B from bonding together.

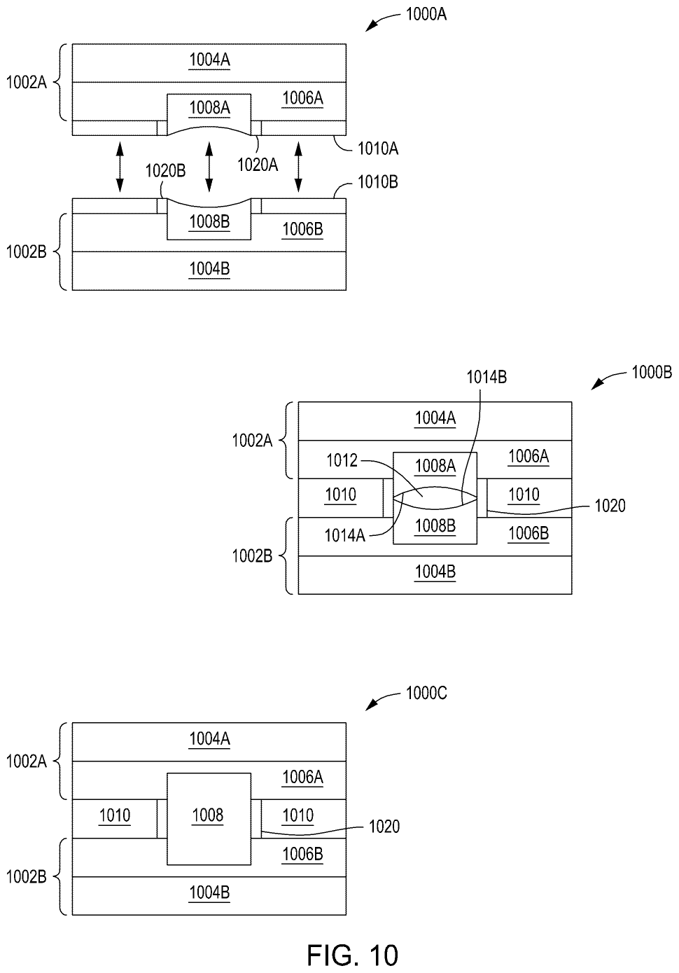

As depicted in a view 1000A of FIG. 10, the substrates 1002A, 1002B may be bonded together using the present methods as described above. In some embodiments, the substrates 1002A, 1002B may include dielectric layers such as, but not limited to, silicon dioxide and/or silicon carbon nitride and the like. In the example, the substrates 1002A, 1002B have silicon layers 1004A, 1004B, silicon dioxide layers 1006A, 1006B, and metal contacts 1008A, 1008B. The bonding layers are aluminum oxide layers 1010A, 1010B. The metal contacts 1008A, 1008B are surrounded by aluminum oxide isolation barriers 1020A, 1020B. As depicted in a view 1000B of FIG. 10, when the substrates 1002A, 1002B with the aluminum oxide isolation barriers 1020A, 1020B are brought into contact with each other (bonded), the aluminum oxide layers 1010A, 1010B form a single aluminum oxide bonded layer 1010. Similarly, the aluminum oxide isolation barriers 1020A, 1020B form a single aluminum oxide isolation barrier 1020 around the metal contacts 1008A, 1008B. The metal contacts 1008A, 1008B have not yet bonded together, and a gap 1012 exists between the metal contacts 1008A, 1008B due to the recesses formed on each metal contact during CMP processing. In order to close the gap 1012 and form a continuous contact, the substrates 1002A, 1002B undergo an annealing process at temperatures up to approximately 400 degrees Celsius. The inventors discovered that by forming the aluminum oxide isolation barriers 1020A, 1020B prior to the annealing process, the aluminum oxide material of did not crystallize at the lower annealing temperatures (at approximately 300 degrees Celsius to approximately 400 degrees Celsius). As depicted in a view 1000C of FIG. 10, the single aluminum oxide bonded layer 1010 does not crystallize and migrate over the surfaces 1014A, 1014B of the metal contacts 1008A, 1008B during the annealing process, allowing the metal contacts 1008A, 1008B to bond together to form a continuous interconnect 1008.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for processing a substrate, comprising:
providing a first substrate for a hybrid bonding process; and
forming, on the first substrate, a hybrid bonding layer that comprises a dielectric layer, a metal contact, and an isolation barrier surrounding the metal contact that is between the metal contact and at least a portion of the dielectric layer.

2. The method of claim 1, further comprising:
hybrid bonding the first substrate to a second substrate via the hybrid bonding layer.

3. The method of claim 1, wherein the isolation barrier is formed of metal or dielectric material.

4. The method of claim 1, wherein the metal contact is formed of copper.

5. The method of claim 1, wherein the isolation barrier is formed of silicon dioxide material.

6. The method of claim 1, wherein the dielectric layer is an aluminum oxide (Al₂O₃) layer.

7. The method of claim 6, wherein the aluminum oxide layer is formed on a dielectric material on the first substrate that is different from a material of the aluminum oxide layer.

8. The method of claim 7, wherein the isolation barrier extends from an uppermost surface of the dielectric material to at least an uppermost surface of the aluminum oxide layer.

9. The method of claim 7, wherein the metal contact is first formed in the dielectric material, a recess is formed a distance from the metal contact in the dielectric material for acceptance of aluminum oxide material, aluminum oxide is then deposited globally on the first substrate, and then the first substrate undergoes a chemical mechanical planarization (CMP) process to form the isolation barrier around the metal contact with a width equal to the distance from the metal contact.

10. The method of claim 9, wherein the distance is greater than a maximum misalignment tolerance value of the hybrid bonding process such that aluminum oxide migration over the metal contact is circumvented during a subsequent annealing process of the hybrid bonding process up to the maximum misalignment tolerance value.

11. The method of claim 7, wherein the aluminum oxide layer is deposited first on the dielectric material, the metal contact is then formed through the aluminum oxide layer, a selective etch process is then used to create a gap surrounding the metal contact, an isolation material is then globally deposited to gapfill the gap surrounding the metal contact, and then a chemical mechanical planarization (CMP) process is used to form the isolation barrier around the metal contact with a width equal to the gap surrounding the metal contact.

12. The method of claim 11, wherein the width is greater than a maximum misalignment tolerance value of the hybrid bonding process such that aluminum oxide migration over the metal contact is circumvented during a subsequent annealing process of the hybrid bonding process up to the maximum misalignment tolerance value.

13. The method of claim 1, wherein a maximum width of the isolation barrier is determined based on a maximum acceptable leakage current through the dielectric layer between adjacent metal contacts.

14. The method of claim 1, wherein the isolation barrier is a distance from the metal contact and wherein the distance between the isolation barrier and the metal contact includes a portion of the dielectric layer with insufficient volume to completely cover the metal contact during a subsequent annealing process of the hybrid bonding process.

15. A substrate prepared for hybrid bonding, comprising:
a dielectric material;
a dielectric bonding layer formed on the dielectric material;
at least one metal contact, wherein an uppermost surface of the at least one metal contact is exposed through the dielectric bonding layer; and
at least one isolation barrier formed around the at least one metal contact that surrounds the at least one metal contact.

16. The substrate of claim 15, wherein the dielectric bonding layer is an aluminum oxide (Al₂O₃) layer, wherein at least one of the at least one metal contact is copper, and wherein the isolation barrier is formed of metal or dielectric material.

17. The substrate of claim 15, wherein the isolation barrier extends from an uppermost surface of the dielectric material to at least an uppermost surface of the dielectric bonding layer.

18. A device, comprising:
the substrate of claim 15; and
another substrate that is hybrid bonded to the substrate via the dielectric bonding layer and the at least one metal contact.

19. A non-transitory, computer readable medium having instructions stored thereon that, when executed, cause a method for processing a substrate, the method comprising:
providing a substrate for a hybrid bonding process; and
forming, on the substrate, a hybrid bonding layer that comprises a dielectric layer, a metal contact, and an isolation barrier surrounding the metal contact that is between the metal contact and at least a portion of the dielectric layer.

20. The non-transitory, computer readable medium of claim 19, the method further comprising wherein the dielectric layer is an aluminum oxide (Al₃O₂) layer formed on a dielectric material on the substrate and at least one of (a) or (b):
(a) wherein the metal contact is first formed in the dielectric material, a recess is formed a distance from the metal contact in the dielectric material for acceptance of aluminum oxide material, aluminum oxide is then deposited globally on the substrate, and then the substrate undergoes a chemical mechanical planarization (CMP) process to form the isolation barrier around the metal contact with a width equal to the distance from the metal contact; or
(b) wherein the aluminum oxide layer is deposited first on the dielectric material, the metal contact is then formed through the aluminum oxide layer, a selective etch process is then used to create a gap surrounding the metal contact, an isolation material is then globally deposited to gapfill the gap surrounding the metal contact, and then a chemical mechanical planarization (CMP) process is used to form the isolation barrier around the metal contact with a width equal to the gap surrounding the metal contact.
